(19) United States
(12) Patent Application Publication
(10) Pub. No.: US 2025/0138089 A1
(43) Pub. Date: May 1, 2025

(54) METHODS AND DEVICES FOR ANALYZING A DEVICE-UNDER-TEST

(71) Applicant: Rohde & Schwarz GmbH & Co. KG, Munich (DE)

(72) Inventors: Gerd BRESSER, Munich (DE); Guido SCHULZE, Grafing (DE)

(73) Assignee: Rohde & Schwarz GmbH & Co. KG, Munich (DE)

(21) Appl. No.: 18/495,863

(22) Filed: Oct. 27, 2023

(51) Int. Cl. G01R 31/317; G01R 23/16

(52) U.S. Cl. CPC G01R 31/31725; G01R 23/16

(57) ABSTRACT

A method for analyzing a device-under-test (DUT) includes feeding a RF signal to the DUT; obtaining and/or storing an input signal waveform of the signal fed to the DUT or an output signal waveform of a signal outputted by the DUT; measuring signal path characteristics of the DUT; calculating an output signal waveform if the input signal waveform is obtained and/or stored or an input signal waveform if the output signal waveform is obtained and/or stored; obtaining clock data from the calculated output signal waveform if the input signal waveform is obtained and/or stored or from the calculated input signal waveform if the output signal waveform is obtained and/or stored, and produce an eye diagram of the calculated output signal waveform if the input signal waveform is obtained and/or stored or of the calculated input signal waveform if the output signal waveform is obtained and/or stored using the obtained clock.

### TECHNICAL FIELD

The present disclosure relates to methods and devices for analyzing a device-under-test, DUT.

### BACKGROUND

There are many known ways to analyze a device-under-test, DUT. A DUT can be any kind of electric or electronic element or group of elements, such as for example cables, electronic circuits, printed circuit boards and so forth. The analysis of characteristics of a DUT provides knowledge about signal changes of signals progressing or traveling through the DUT. Various different parameters can be measured and analyzed as the characteristics of the DUT. In the following description, all these different parameters and characteristics are labeled as signal path characteristics. Hereby, analyzing methods in the time and the frequency domain are generally available to analyze the signal path characteristics of a DUT. Time domain reflectometry, TDR, is an example for a time domain analysis. TDR can be used to obtain spatial information about what is happening to a signal as it travels through a DUT. The TDR result shows where reflections are occurring in the DUT. A vector network analyzer, VNA, normally works in the frequency domain. A VNA measures the so-called scattering parameters, i.e. the signal path characteristics, of a DUT and displays the results in the frequency domain. These frequency domain results can be transformed into the time domain using an inverse FFT (Fast Fourier Transformation). It has to be noted that a VNA normally measures the scattering parameters of an unknown DUT on the basis of a known input signal. The results of signal path characteristics analysis of a DUT can for example be visualized by a so-called eye diagram, which is also called an eye pattern.

Eye diagrams as intuitive graphical representations of electrical or optical digital communication signal are known e.g. from the chapter “Eye diagrams” of the book “Analysis and Design of Transimpedance Amplifiers for Optical Receivers”, pages 413—First Edition. Eduard Säckinger. 2018 John Wiley & Sons, Inc. Published 2018 by John Wiley & Sons, Inc, the disclosure of which is hereby incorporated by reference. Figure B.3 of this publication shows a measurement setup of an eye diagram with an oscilloscope. Also, clock determination/recovery and different possible implementations thereof is mentioned with reference to this figure.

### SUMMARY

A method for analyzing a device-under-test, DUT, comprises the steps of:
Feeding a RF signal to the DUT,
Obtaining, especially using an oscilloscope, and/or storing an input signal waveform of the signal fed to the DUT or an output signal waveform of a signal outputted by the DUT,
Measuring, especially using a VNA, signal path characteristics of the DUT,
Calculating an output signal waveform in the case that the input signal waveform is obtained and/or stored or an input signal waveform in the case that the output signal waveform is obtained and/or stored, by applying the measured signal path characteristics to the input signal waveform in the case that the input signal waveform is obtained and/or stored or to the output signal waveform in the case that the output signal waveform is obtained and/or stored,
Obtaining clock data from the calculated output signal waveform in the case that the input signal waveform is obtained and/or stored or from the calculated input signal waveform in the case that the output signal waveform is obtained and/or stored, and
Producing an eye diagram representation of the calculated output signal waveform in the case that the input signal waveform is obtained and/or stored or of the calculated input signal waveform in the case that the output signal waveform is obtained and/or stored, using the obtained clock.

The advantage of the method according to the first aspect is that a user can directly see, using the analysis data, how a signal will look like once it passes the DUT. Thus, the DUT, if necessary, can be tuned and adapted for better performance and the result of this tuning can be directly seen in a visualization of the analysis data.

The DUT may be a filter or a cable such as e.g. a USB cable. The RF signal is fed to the near end or the far end of the DUT, the DUT being a cable. The terms “near-end” and “far-end” are based on which end of the cable the test fixture is attached in relation to the device being tested. The measurement is made either “near” the device or “far” from the device being tested. The invention can thus be used e.g. for USB compliance tests based on the produced eye diagram.

In an optional implementation of the method of the first aspect, the step of measuring the signal path characteristics of the DUT comprises applying a TDR (time domain reflectometry) measurement to the DUT. Hereby, in an optional implementation, the step of determining the output waveform comprises embedding a result of the TDR measurement with a near-end version of the waveform signal. In an alternative implementation, the step of determining the output waveform comprises de-embedding a result of the TDR measurement from a far-end version of the waveform signal.

With respect to the above-mentioned TDR measurement, it is noted that in addition to or as an alternative of said TDR measurement, a TDT (time domain transmissometry) measurement may be applied to the DUT.

In a further optional implementation of the method of the first aspect or one of its optional implementations, the step of determining analysis data of the signal path characteristics of the DUT comprises the steps of determining a group delay of the output waveform, determining clock data of the waveform signal input to the DUT using the obtained clock data of the output waveform and the determined group delay of the output waveform, and obtaining the analysis data by comparing the waveform signal input to the DUT and the determined output waveform using the determined clock data of the waveform signal input to the DUT and the obtained clock data of the output waveform. In an optional implementation, the step of obtaining the input signal comprises receiving the waveform signal in real time when being input to the DUT or receiving the waveform signal as a stored file. In a further optional implementation, the clock data of the output waveform are obtained from timing of edges and a symbol rate of the output waveform and the clock data of the waveform signal input to the DUT are determined from a timing of edges and a symbol rate of the waveform signal input to the DUT. In a further optional implementation, the method comprises the steps of slicing the output waveform into first frames and aligning the first frames to obtain a first eye diagram, and slicing the waveform signal input to the DUT into second frames and aligning the second frames to obtain a second eye diagram. Hereby, in an optional implementation, the step of obtaining the analysis data comprises the step of comparing, especially overlaying, the first and the second eye diagram.

With respect to the above-mentioned first eye diagram or the second eye diagram, respectively, it is noted that it is particularly advantageous if the method comprises the step of performing a jitter analysis on the basis of the first eye diagram or the second eye diagram or the comparison, especially the overlay, of the first and the second eye diagram. Additionally or alternatively, the method may comprise the step of doing at least one marker on the first eye diagram and/or the second eye diagram.

In a second aspect of the present disclosure, a method for analyzing a DUT comprises the steps of determining an output waveform of the DUT, said output waveform being output by the DUT in response to a waveform signal being input to the DUT, obtaining clock data from the output waveform, determining a group delay of the output waveform, determining clock data of the waveform signal input to the DUT using the obtained clock data of the output waveform and the determined group delay of the output waveform, and obtaining analysis data by comparing the waveform signal input to the DUT and the determined output waveform using the determined clock data of the waveform signal input to the DUT and the obtained clock data of the output waveform.

The advantages of the method according to the second aspect are the obtained analysis data allowed to directly see and analyze the potential differences between the waveform signal input to the DUT and the determined output waveform. This allows a quick and reliable analyzation of DUTs using the analysis data or a visualization of the analysis data in an eye diagram with their impact on the input signal including a potential distortion of the signal.

In an optional implementation of the method of the second aspect, the waveform signal input to DUT is received in real time when being input to the DUT or is received as a stored file.

In a further optional implementation of the method of the second aspect or its previous implementation, the clock data of the output waveform are obtained from a timing of edges and a symbol rate of the output waveform and the clock data of the waveform signal input to the DUT are determined from a timing of edges and a symbol rate of the waveform signal input to the DUT.

In a further optional implementation of the method of the second aspect or its implementations, the method further comprises the steps of slicing the output waveform into first frames and aligning the first frames to obtain a first eye diagram, and slicing the waveform signal input to the DUT into second frames and aligning the second frames to obtain a second eye diagram. Hereby, in a further optional implementation, the step of obtaining the analysis data comprises the step of comparing, especially overlaying, the first and the second eye diagram. In a further optional implementation of the method of the second aspect or its implementations, the step of determining the output waveform of the DUT comprises the steps of obtaining the waveform signal input to the DUT, measuring signal path characteristics of the DUT, and determining the output waveform by applying the measured signal path characteristics to the input signal. Hereby, in a further optional implementation, the step of measuring the signal path characteristics of the DUT comprises applying a TDR measurement to the DUT. Hereby, in a further optional implementation, the step of determining the output waveform comprises embedding a result of the TDR measurement with a near-end version of the waveform signal. In an alternative implementation, the step of determining the output waveform comprises de-embedding a result of the TDR measurement from a far-end version of the waveform signal.

In a third aspect of the present disclosure, an apparatus for analyzing a DUT is provided, which is configured to perform either the method according to the first aspect, or the method according to the second aspect. In optional implementations of the apparatus, the apparatus is configured to the form any single one or a combination of the implementations of the first or the second aspect. In an optional implementation of the apparatus of the third aspect, the apparatus is a vector network analyzer, VNA.

It has to be noted that all apparatuses, devices, elements, units and means described in the present disclosure can be implemented in and by software or hardware elements or any kind of combination thereof. All steps which are performed by the methods and the various apparatuses and entities described in the present disclosure are intended to mean that the respective apparatus or entity is adapted to or configured to perform the respective steps and functionalities. Even if, in the following description of the specific embodiments, a specific functionality or step to be performed by external entities or apparatuses is not reflected in the description of the specific detailed element of that entity which performs that specific step of functionality, it shall be clear for a skilled person that those methods and functionalities can be implemented in a respective software or hardware elements, or any kind of combination thereof.

### BRIEF DESCRIPTION OF DRAWINGS

The above described aspects and implementations of the present disclosure will be explained in the following description of specific embodiments in relation to the enclosed drawings, in which

FIG. 1 shows a flow chart of a method for analyzing a DUT according to the first aspect,

FIGS. 2a and 2b show respective alternative optional implementations of a step of the method of the first aspect,

FIG. 3 shows a flow chart of an optional implementation of another step of the method of the first aspect,

FIG. 4 shows a flow chart of a method for analyzing a DUT according to a second aspect,

FIG. 5 shows a flow chart of an optional implementation of a step of the method of the second aspect, and

FIG. 6 shows a schematic block diagram of an apparatus (e.g. VNA) for analyzing a DUT and a DUT according to the present disclosure.

### DETAILED DESCRIPTION

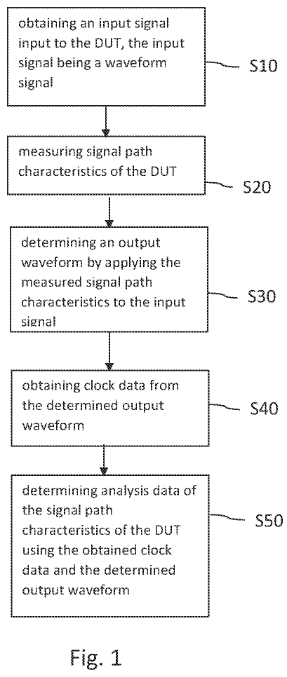

FIG. 1 shows a schematic flow chart of a method for analyzing a DUT (device under test), according to a first aspect of the present disclosure. The analyzing method according to the first aspect comprises the steps of obtaining, S10, an input signal fed to a DUT, the input signal being a waveform signal, measuring, S20, signal path characteristics of the DUT, determining, S30, an output waveform by applying the measured signal path characteristics to the input signal, obtaining, S40, clock data from the determined output waveform, and determining, S50, analysis data of the signal path characteristics of the DUT using the obtained clock data and the determined output waveform.

For the sake of completeness, also in accordance with the first aspect, it is noted that the method may alternatively comprise the steps of obtaining an output signal outputted by a DUT, the output signal being a waveform signal, measuring signal path characteristics of the DUT, determining an input waveform by applying the measured signal path characteristics to the output signal, obtaining clock data from the determined input waveform, and determining analysis data of the signal path characteristics of the DUT using the obtained clock data and the determined input waveform.

The general idea underlying the method according to the first aspect of the present disclosure is to provide analysis data, that can be visualized for example in the form of eye diagrams, of a DUT for real (i.e. not simulated) input signals. Hereby, an input signal in form of a waveform signal is obtained either in real time, for example from an oscilloscope, which measures and outputs an unknown input signal in real time, or the waveform signal is obtained from a stored file. The stored file could also for example be based on an unknown input signal, which is detected and measured by an oscilloscope, which then stores this input signal as a waveform signal. A waveform signal is a continuous signal in the time domain.

In a next step S20, the signal path characteristics of the DUT are measured. The signal path characteristics of the DUT are for example scattering parameters, also called S-parameters, or any other suitable parameter(s), as analyzed and measured by the vector network analyzer, VNA, or any other suitable device. That is, the method according to the first aspect of the present disclosure as well as the method according to the second aspect of the present disclosure as explained in detail further below, are for example implemented by a VNA. That is, after the input signal input in the DUT is obtained according to step S10, and the signal path characteristics of the DUT are measured according to step S20, an output waveform is determined in the following step, S30, by applying the measured signal path characteristics to the obtained input signal. The clock data, in a succeeding step S40, are obtained from the determined output waveform. This then allows, for the succeeding step S50, to determine analysis data of the signal path characteristics of the DUT using the obtained clock data and the determined output waveform.

With respect to the above-mentioned scattering parameters or S-parameters, respectively, it is noted that it might be particularly advantageous if said scattering parameters or S-parameters, respectively, are determined or measured based on continuous-wave signals.

Furthermore, with respect to the above-mentioned any other suitable device, it is noted that such a device may especially be understood as a device being suitable for measuring scattering parameters or S-parameters, respectively.

It is further noted that it might be particularly advantageous if performing a measurement with the aid of the above-mentioned VNA or the any other suitable device, respectively, comprises measuring the corresponding step response of the DUT especially transformed into the time domain.

The analyzing method of the first aspect uses the combined strength of an oscilloscope, which can be used to obtain the input signal to the DUT either in real time or stored as a stored file and a VNA, which is adapted to measure signal path characteristics of the DUT: The resulting advantage is that a user can directly see, from the visualization of the determined analysis data of the signal path characteristics of the DUT, what the signal looks like once it passes the DUT. This means that the user can tune a DUT and see the resulting impact on the visualization/representation of the analysis data, for example in an eye diagram. This means that mask testing and other analysis can be performed to obtain statistical data and to obtain in-depth details about the signal path characteristics of the DUT. Further details as to the representation with an oscilloscope can be taken from the chapter “Eye diagrams” of the book “Analysis and Design of Transimpedance Amplifiers for Optical Receivers”, pages 413—First Edition. Eduard Säckinger. 2018 John Wiley & Sons, Inc. Published 2018 by John Wiley & Sons, Inc.

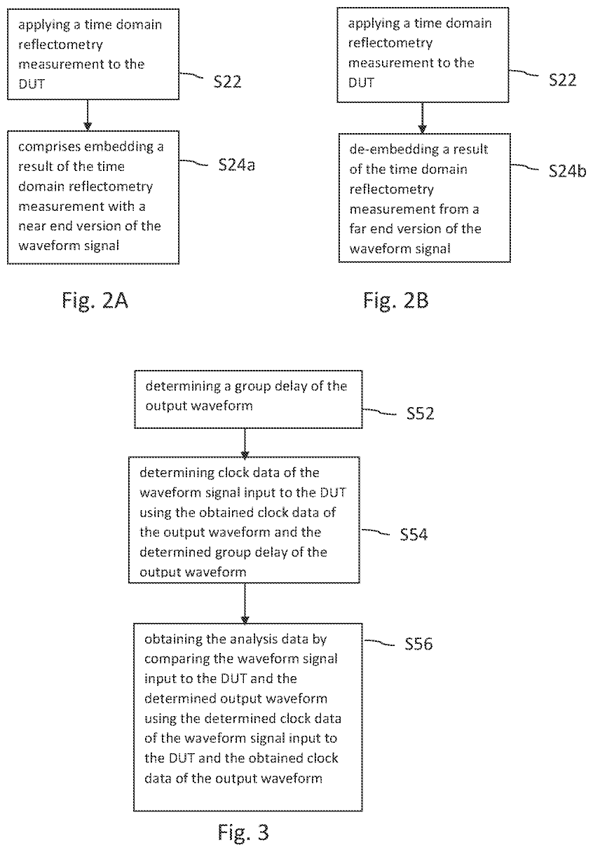

Step S20 of the analyzing method of FIG. 1 could, in an optional implementation, be implemented so that the step of measuring the signal path characteristics of the DUT comprises the step of applying a TDR measurement to the DUT, shown as step S22 in FIGS. 2a and 2b. Hereby, the succeeding step S30 of determining an output waveform could be implemented into optional alternative implementations, which are respectively shown as steps S24a and S24b in the flowcharts of FIGS. 2a and 2b. In a first alternative, the step S20 of determining the output waveform could comprise the step S24a of embedding a result of the TDR measurement with a near-end version of the waveform signal. In the alternative shown in FIG. 2b, the step S30 of determining the output waveform may comprise the step S24b of de-embedding a result of the TDR measurement from a far end version of the waveform signal. A visualization of the meaning of “far” and “near” end is presented in FIG. 6.

The TDR measurement applied in the optional implementation step S22 is for example performed in a VNA. Hereby, the implementation of the TDR measurement is well known for a skilled person and generally involves the sending out of a signal, which for example involves a voltage step or the like, into the DUT, the measuring of a reflected signal and the mathematical combination of the signal that has been send out and the reflected signal in order to obtain information about the signal path characteristics of the DUT. Typically, the result of a TDR of the measurement, TDR measurement, is the ratio of a reflected voltage to the transmitted voltage and is called the reflection coefficient. The TDR is normally performed in the time domain. However, a VNA normally operates in the frequency domain, but the measurement results obtained by a VNA in the frequency domain can be transformed into the time domain on the basis of an inverse FFT or the like. All these detailed implementations are within the normal knowledge of a skilled person.

In an optional implementation of step S15 of determining analysis data of the signal path characteristics of the DUT, the steps S52, S54 and S56 as shown in the flow chart of FIG. 3 are comprised. S52 is a step of determining a group delay of the output waveform, step S54 is a step of determining clock data of the waveform signal input to the DUT using the obtained clock data of the output waveform and the determined group delay of the output waveform, and step S56 is the step of obtaining the analysis data by comparing the waveform signal input to the DUT and the determined output waveform using the determined clock data of the waveform signal input into the DUT and the obtained clock data of the output waveform. A skilled person knows how to implement, to determine or to obtain a group delay of a waveform signal. Specifically, a group delay is a measure of the phase distortion of a DUT. Hereby, the group delay is the actual transit time of a signal through a DUT as a function of the frequency. Also, the group delay can be regarded as the derivative of the DUT's phase characteristic with respect to the frequency. Typically, the phase characteristics of the DUT consists of linear and high order phase-shift components. The group delay generally depicts the amount of time it takes for each frequency in the signal to travel through the DUT. The obtaining or determining of clock data according to the present disclosure can be implemented by any suitable clock recovery algorithm.

With respect to the above-mentioned group delay, it is noted that it might be particularly advantageous if the method comprises the step of using the group delay to adapt the timing of the output signal to get the timing information of the input signal, especially the real input signal.

In an optional implementation of step S40, the clock data of the input waveform are obtained from a timing of edges and a symbol rate of the output waveform and the clock data of the waveform signal input into the DUT are obtained from a timing of edges and a symbol rate of the waveform signal input to the DUT. A skilled person knows how to obtain the edges and a symbol rate of waveform signals and also how to obtain the clock data of waveform signals from the common general knowledge.

In an optional implementation, step S50 comprises the steps of slicing the output waveform into first frames and aligning the first frames to obtain a first eye diagram, and slicing the waveform signal input to the DUT into second frames and aligning the second frames to obtain a second eye diagram. Hereby, in a further optional implementation, step S50 further comprises the step of comparing, especially overlaying, the first and the second eye diagram in order to obtain the analysis data. In this case, the analysis data are the overlaid first and second eye diagram giving the user a visualization of the analyzation result. A skilled person knows how to slice waveform signals into frames and how to create and interpret an eye diagram.

With respect to the above-mentioned first frames or second frames, respectively, it is noted that it might be particularly advantageous if for forming said first frames and/or said second frames, clock-data recovery is applied especially to determine the corresponding timing information.

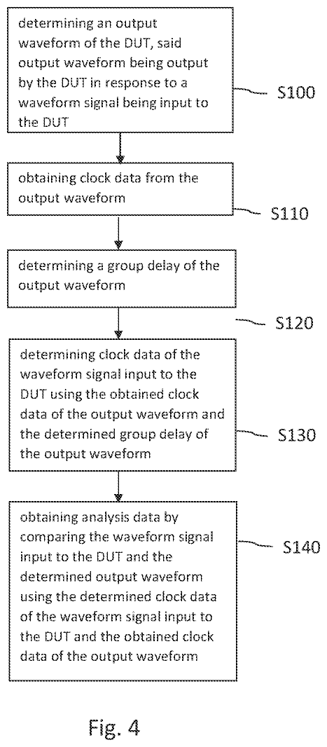

FIG. 4 shows a schematic flow diagram of a method for analyzing a DUT according to a second aspect of the present disclosure. The analyzing method according to the second aspect comprises the steps of determining, S100, an output waveform of the DUT, said output waveform being output by the DUT in response to a waveform signal being input to the DUT, obtaining, S110, clock data from the output waveform, determining, S120, a group delay of the output waveform, determining, S130, clock data of the waveform signal input to the DUT using the obtained clock data of the output waveform and the determined group delay of the output waveform, and obtaining, S140, analysis data by comparing the waveform signal input into the DUT and the determined output waveform using the determined clock data of the waveform signal input into the DUT and the obtained clock data of the output waveform. It has to be noted that the description and explanation of the analyzing method of the second aspect uses similar and same terminology as the description and explanation of the analyzing method of the first aspect. The same and similar terminology and method steps mean the same technical content, so that redundant description is omitted and reference is being made to the respective terms and terminology used in the description of the first aspect. For example, step S100 of the analyzing method of the second aspect as shown in FIG. 4 corresponds to step S30 of the analyzing method of the first aspect. Step S110 of the method of the second aspect corresponds to step S40 of the method of the first aspect. Step S120 corresponds to step S52 of the optional implementation of the method of the first aspect shown on FIG. 3. Step 130 of the method of the second aspect corresponds to step S54 of FIG. 3. Step S40 of the method of the second aspect corresponds to step S56 of the potential implementation of the method of the first aspect shown in FIG. 3. Consequently, the technical explanations used in relation to the method of the first aspect identically apply to the corresponding once of the method of the second aspect.

With respect to the above-mentioned group delay, it is noted that it might be particularly advantageous if the method comprises the step of using the group delay to adapt the timing of the output signal to get the timing information of the input signal, especially the real input signal.

Generally, the analyzing method of the second aspect is directed to the use of a recovered clock data from the output waveform, which has for example been determined by VNA, and the average group delay of the VNA measurement in order to determine the clock of the input signal and thus compare the input and the output signal in suitable analysis data, for example by overlaying eye diagrams. The advantages of the analyzing method of the second aspect are that the analyzing data, i.e. the eye diagrams of the input waveform signal and the output waveform can be overlaid to visually see the difference or to do further analysis on the input and output eye diagrams. Further, active and passive DUTs can be analyzed visually via a comparison of the eye diagrams with their impact on the input signal including the distortion of the signal.

In an optional implementation of the method according to the second aspect, the waveform input signal to the DUT is received either in real time when being input to the DUT, for example by means of an oscilloscope, or is received as a stored file, similar to the optional implementation of the method according to the first aspect.

In an optional implementation of step S110 of the method according to the second aspect, the clock data of the output waveform are obtained from a timing of edges and a symbol rate of the output waveform and the clock data of the waveform signal input to the DUT are determined from a timing of edges and a symbol rate of the waveform signal input to the DUT.

In a further optional implementation of the method of the second aspect, the method comprises the steps of slicing the output waveform into first frames and aligning the first frames to obtain a first eye diagram, and slicing the waveform signal input to the DUT into second frames and aligning the second frames to obtain a second eye diagram. Hereby, in further optional implementation, the step of obtaining the analysis data, S140, comprises the step of comparing, especially overlaying, the first and the second eye diagram.

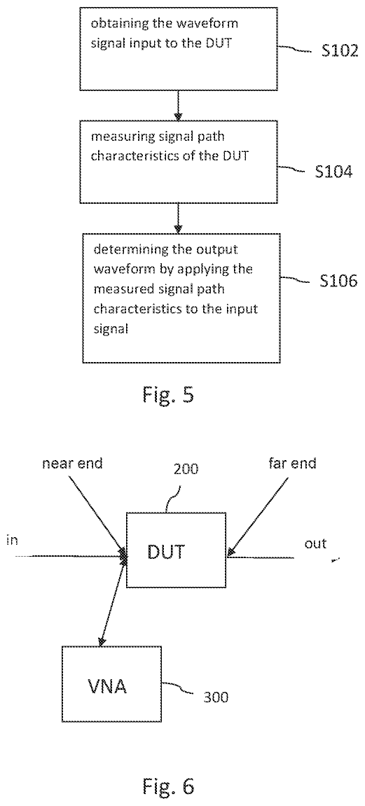

In a further optional implementation of the analyzing method of the second aspect, the step 100 of determining the output waveform of the DUT comprises the steps of obtaining, S102, the waveform signal input to the DUT, measuring, S104, signal path characteristics of the DUT and determining, S106, the output waveform by applying the measured signal path characteristics to the input signal. This optional implementation form is shown in the flow diagram of FIG. 5. Hereby, in an optional implementation, the step S104 of measuring the signal path characteristics of the DUT can comprise applying a TDR measurement or TDT measurement to the DUT. Reference is being made to the explanations regarding the method of the first aspect, as for example regarding steps S22 of FIGS. 2a and 2b. In the same way, also for the method of the second aspect, the step S100 may comprise embedding a result of the TDR or TDT measurement with a near-end version of the waveform signal, or de-embedding a result of the TDR measurement from a far-end version of the waveform signal.

As to this reconstruction, reference is made to EP 1 424 565. This reconstruction, nowadays made with the aid of a VNA, a processor and the method described below and can also be performed by an instrument having the characteristics and processing capabilities of a VNA.
For the reconstruction of the eye-diagram at the end of any track previously measured and characterized, the steps to be made are as follows:
Receiving at the VNA a real input signal pattern;
Calculating the Fourier Transform (FFT) of said real input signal pattern
Determination of the real input signal pattern in the frequency domain at the connection end, through a product between the FFT of said real input signal pattern and the transfer function proper of the connection.

A third aspect of the present disclosure is directed to an apparatus for analyzing a DUT. Such an apparatus can for example be implemented as a VNA or any other suitable device. Hereby, the apparatus according to the third aspect implements either the functionalities of the method steps of the analyzing method according to the first aspect as described in relation to FIG. 1 and its optional implementations, or the functionalities of the method steps of the analyzing method of the second aspect as shown in FIG. 4 and its optional implementations. In other words, the apparatus according to the third aspect comprises means, units, elements or the like, which are respectively adapted to implement and perform the various method steps described above in relation to the analyzing method of the first and second aspects, as well as the various optional implementations as explained in relation to FIGS. 1 to 5 above. These functionalities can be implemented in the apparatus according to the third aspect as software or hardware or any kind of suitable combination thereof. FIG. 6 shows a schematic block diagram of an arrangement of an apparatus according to the third aspect in the form of am VNA 300 and a DUT 200. As shown, the VNA 300 is connected to an input port to a DUT 200 in order to measure signal path characteristics of the DUT 200 for example by a TDR measurement. The arrows labelled “in” and “out” on the DUT 200 characterize the input and output directions, respectively, of the normal signal flow through the DUT 200. Further, FIG. 6 schematically shows, in form of the two arrows labeled “far” and “near”, the locations where an oscilloscope can obtain or measure and an input signal input to the DUT, the input signal being a waveform signal. As explained above, for example in relation to step S10 of the method of the first aspect of FIG. 1, the input signal could for example be obtained by the VNA 300 in real time from an oscilloscope, or could be measured by an oscilloscope and then stored in a file, so that it is obtained as a stored file. For an explanation of the “near”-end and “far”-end versions of the waveform signal obtained by the VNA 300, reference is made to the explanations above, e.g. in relation to steps S24a and S24b in FIGS. 2a and 2b, respectively.

The present disclosure and the methods according to the first and second aspect as well as the apparatus according to the first aspect have been described in conjunction with various examples and implementations. However, other variations can be understood and effected by those persons skilled in the art and practicing the described disclosure, from the studies of the drawings, the description and the claims. In the claims as well as the description, the word “comprising” does not exclude other steps, functionalities or elements, and the indefinite article “a” or “an” does not exclude a plurality. A single element or other functionality may fulfill a functionality of several entities or items. The mere fact that certain functionalities or steps are recited in the mutually different dependent claims does not indicate that a combination of these functionalities cannot be used in advantageous implementations, but rather that such potential combinations are possible and understood by a skilled person.

1. A method for analyzing a device-under-test, DUT, wherein the method comprises the steps of:
Feeding a RF signal to the DUT,
Obtaining, especially using an oscilloscope, and/or storing an input signal waveform of the signal fed to the DUT or an output signal waveform of a signal outputted by the DUT,
Measuring, especially using a VNA, signal path characteristics of the DUT,
calculating an output signal waveform in the case that the input signal waveform is obtained and/or stored or an input signal waveform in the case that the output signal waveform is obtained and/or stored by applying the measured signal path characteristics to the input signal waveform in the case that the input signal waveform is obtained and/or stored or to the output signal waveform in the case that the output signal waveform is obtained and/or stored,
obtaining clock data from the calculated output signal waveform in the case that the input signal waveform is obtained and/or stored or from the calculated input signal waveform in the case that the output signal waveform is obtained and/or stored, and
produce an eye diagram representation of the calculated output signal waveform in the case that the input signal waveform is obtained and/or stored or of the calculated input signal waveform in the case that the output signal waveform is obtained and/or stored using the obtained clock.

2. The method of claim 1, wherein the DUT is a filter or a cable such as e.g. a USB cable.

3. The method of claim 2, wherein the RF signal is fed to the near end or the far end of the DUT, the DUT being a cable.

4. The method according to claim 1, wherein
the step of measuring the signal path characteristics of the DUT comprises applying a TDR measurement to the DUT.

5. The method according to claim 1,
further comprising the steps of
determining a group delay of the output signal waveform,
determining clock data of the input signal waveform using the obtained clock data of the output signal waveform and the determined group delay of the output signal waveform, and
produce an eye diagram representation of the input signal waveform and the determined output signal waveform using the determined clock data of the input signal waveform and the obtained clock data of the output signal waveform.

6. The method according to claim 5, wherein the step of obtaining the input signal comprises receiving the waveform signal in real time when being input to the DUT or receiving the waveform signal as a stored file.

7. The method according to claim 5, wherein the clock data of the output waveform are obtained from a timing of edges and a symbol rate of the output waveform and the clock data of the waveform signal input to the DUT are determined from a timing of edges and a symbol rate of the waveform signal input to the DUT.

8. The method according to claim 5, comprising the steps of slicing the output waveform into first frames and aligning the first frames to obtain a first eye diagram, and slicing the waveform signal input to the DUT into second frames and aligning the second frames to obtain a second eye diagram.

9. The method according to claim 8, wherein the step of obtaining the analysis data comprises the step of comparing, especially overlaying, the first and the second eye diagram.

10. A method for analyzing a device-under-test, DUT, wherein the method comprises the steps of:
determining an output waveform of the DUT, said output waveform being output by the DUT in response to a waveform signal being input to the DUT,
obtaining clock data from the output waveform,
determining a group delay of the output waveform,
determining clock data of the waveform signal input to the DUT using the obtained clock data of the output waveform and the determined group delay of the output waveform, and
obtaining analysis data by comparing the waveform signal input to the DUT and the determined output waveform using the determined clock data of the waveform signal input to the DUT and the obtained clock data of the output waveform.

11. The method according to claim 10, wherein the waveform signal input to the DUT is received in real time when being input to the DUT or received as a stored file.

12. The method according to claim 10, wherein the clock data of the output waveform are obtained from a timing of edges and a symbol rate of the output waveform and the clock data of the waveform signal input to the DUT are determined from a timing of edges and a symbol rate of the waveform signal input to the DUT.

13. The method according claim 10, comprising the steps of slicing the output waveform into first frames and aligning the first frames to obtain a first eye diagram, and slicing the waveform signal input to the DUT into second frames and aligning the second frames to obtain a second eye diagram.

14. The method according to claim 13, wherein the step of obtaining the analysis data comprises the step of comparing, especially overlaying, the first and the second eye diagram.

15. The method according to claim 10, wherein the step of determining the output waveform of the DUT comprises the steps of
obtaining the waveform signal input to the DUT,
measuring signal path characteristics of the DUT, and
determining the output waveform by applying the measured signal path characteristics to the input signal.

16. The method according to claim 15, wherein
the step of measuring the signal path characteristics of the DUT comprises applying a TDR measurement to the DUT.

17. The method according to claim 16, wherein
the step of determining the output waveform comprises embedding a result of the TDR measurement with a near end version of the waveform signal.

18. The method according to claim 16, wherein
the step of determining the output waveform comprises de-embedding a result of the TDR measurement from a far end version of the waveform signal.

19. A measurement system for analyzing a device-under-test, DUT, configured to perform the method according to claim 1.
